(19) United States
(12) Patent Application Publication
(10) Pub. No.: US 2024/0292614 A1
(43) Pub. Date: Aug. 29, 2024

(54) MEMORY SEMICONDUCTOR DEVICE AND FABRICATION METHOD THEREOF

(71) Applicant: YANGTZE MEMORY TECHNOLOGIES CO., LTD., Wuhan (CN)

(72) Inventors: Yihuan WANG, Wuhan (CN); Wugen HUANG, Wuhan (CN); Liang XIAO, Wuhan (CN); Lina MIAO, Wuhan (CN)

(21) Appl. No.: 18/326,676

(22) Filed: May 31, 2023

(30) Foreign Application Priority Data
Feb. 24, 2023 (CN) 202310175092.6

(51) Int. Cl. H10B 43/27; H10B 41/27

(52) U.S. Cl. CPC H10B 43/27; H10B 41/27

(57) ABSTRACT

A method includes forming storage channel structures including a functional layer, a channel layer, a filling layer and a slit in the filling layer, thinning a first substrate to form a second substrate, removing a second bottom section outside the second substrate to expose a first bottom section slit, filling a dielectric material layer in the first bottom section slit, removing the second substrate and a first bottom section functional layer to form a first dielectric section filled in the first bottom section slit and expose a first bottom section channel layer, forming a common source layer contacting the first bottom section channel layer, the first bottom section filling layer and the first dielectric section. After inverting the stack structure, the substrate is thinned, and the exposed functional layer and the channel layer are removed.

### CROSS-REFERENCE TO RELATED APPLICATION

This application claims the priority of Chinese Patent Application No. 202310175092.6, filed on Feb. 24, 2023, titled, “Semiconductor Device and Its Manufacturing Method, Storage System, Electronic Equipment,” and incorporated herein by reference in its entirety.

### TECHNICAL FIELD

The present application relates to the field of semiconductors, specifically to a semiconductor device and a fabrication method thereof, a memory system and an electronic apparatus.

### BACKGROUND

Because NAND flash memory is a non-volatile memory product with low power consumption, light weight, and good performance that can retain stored information in case of power loss, it is widely applied in electronic products. 3D NAND (three-dimensional memory) is a novel kind of flash memory that can further improve storage capacity and reduce storage cost relative to 2D NAND flash memory.

### SUMMARY

The present application provides a semiconductor device and a fabrication method thereof, a memory system and an electronic apparatus that can address the technical problems of non-uniform depths of channel structures in a plurality of memory strings currently formed on the substrate and the resultant reduced yield of semiconductor devices.

The present application provides a fabrication method of a semiconductor device comprising: forming a stack structure comprising gate conductive layers and interlayer insulating layers alternatively stacked on a first lateral surface of a first substrate and storage channel structures extending in the stack structure and into the first substrate in a longitudinal direction perpendicular to the first lateral surface, the storage channel structures having a functional layer, a channel layer, a filling layer and a slit in the filling layer; thinning the first substrate from a side of the first substrate away from the first lateral surface to form a second substrate and expose a first channel structure of the storage channel structures, the first channel structure comprising a second bottom section exposed from the second substrate and a first bottom section in the second substrate, the first bottom section comprising a first bottom section channel layer, a first bottom section functional layer, a first bottom section filling layer and a first bottom section slit; removing the second bottom section and exposing the first bottom section slit at the first bottom section; filling a dielectric material layer in the first bottom section slit; removing the second substrate and the first bottom section functional layer at the first bottom section to form a first dielectric section filled in the first bottom section slit, and expose the first bottom section channel layer of the first bottom section; forming a common source layer contacting the first bottom section channel layer, the first bottom section filling layer and the first dielectric section.

In some implementations, the second bottom section includes a second bottom section channel layer, a second bottom section filling layer on an inner side of the second bottom section channel layer and a second bottom section functional layer on an outer side of the second bottom section channel layer; the step of removing the second bottom section comprises: removing the second bottom section functional layer on the outer side of the second bottom section channel layer of the second bottom section to expose the second bottom section channel layer of the second bottom section; removing the second bottom section channel layer at the second bottom section to expose the second bottom section filling layer on the inner side of the second bottom section channel layer of the second bottom section; and removing the second bottom section filling layer.

In some implementations, the step of removing the second bottom section filling layer on the inner side of the second bottom section channel layer of the second bottom section comprises: removing the second bottom section filling layer on the inner side of the second bottom section channel layer of the second bottom section, and thinning the first bottom section functional layer on the outer side of the first bottom section channel layer of the first bottom section to form a first recess; the step of filling the dielectric material layer in the first bottom section slit comprises: forming a dielectric material layer on the second substrate to fill the dielectric material layer in the first bottom section slit and the first recess; the step of forming the first dielectric section filled in the first bottom section slit comprises: removing the dielectric material layer outside the first bottom section slit to form the first dielectric section filled in the first bottom section slit.

In some implementations, the step of removing the dielectric material layer outside the first bottom section slit comprises: removing the dielectric material layer on the second substrate; removing the dielectric material layer in the first recess and thinning the dielectric material layer in the first bottom section slit to form the first dielectric section filled in the first bottom section slit.

In some implementations, the step of forming the dielectric material layer on the second substrate to fill the dielectric material layer in the first bottom section slit and the first recess comprises: forming the dielectric material layer on the second substrate to fill the dielectric material layer in the first bottom section slit and the first recess to form a second dielectric section in the first recess; the step of removing the dielectric material layer in the first recess comprises: removing the second dielectric section; wherein the step of removing the second substrate is between the step of removing the dielectric material layer on the second substrate and the step of removing the second dielectric section.

In some implementations, the step of removing the first bottom section functional layer at the first bottom section comprises: removing the first bottom section functional layer at the first bottom section, removing the second dielectric section, thinning the first bottom section filling layer at the first bottom section and thinning the dielectric material layer in the first bottom section slit.

In some implementations, the first bottom section functional layer comprises a first oxide layer, a first nitride layer and a second oxide layer, wherein the first nitride layer is between the first oxide layer and the second oxide layer, and the first oxide layer is on a side of the first nitride layer away from the first bottom section channel layer; the step of removing the first bottom section functional layer at the first bottom section comprises: removing the first oxide layer, removing the first nitride layer and removing the second oxide layer.

In some implementations, the stack structure further comprises a termination layer between the first substrate and the gate conductive layer and the interlayer insulating layer; the semiconductor device further comprises a first insulating layer on a side of the termination layer away from the gate conductive layer; the step of removing the first oxide layer comprises: removing the first oxide layer and removing the first insulating layer.

The present application further provides a semiconductor device comprising: a stack structure comprising gate conductive layers and interlayer insulating layers alternatively stacked in a longitudinal direction, and storage channel structures penetrating the stack structure in the longitudinal direction, the storage channel structures having a bottom section protruding from a first side of the stack structure; and a common source layer on the first side of the stack structure; wherein the storage channel structures comprise a first channel structure having a first bottom section, the first bottom section comprises a first bottom section channel layer, a first bottom section filling layer and a first dielectric section on an inner side of the first bottom section channel layer, and the common source layer is disposed to contact the first bottom section channel layer, the first bottom section filling layer and the first dielectric section.

In some implementations, the first bottom section further comprises a first bottom section slit sealed by the first bottom section filling layer and the first dielectric section.

In some implementations, the storage channel structures further comprise a second channel structure having a third bottom section, and the third bottom section comprises a third bottom section channel layer and a third bottom section filling layer on an inner side of the third bottom section channel layer; wherein the common source layer is disposed to contact the third bottom section channel layer.

In some implementations, the third bottom section further comprises a third bottom section slit located in and scaled by the third bottom section filling layer.

In some implementations, the third bottom section channel layer at the third bottom section has a height in the longitudinal direction smaller than that of the first bottom section channel layer at the first bottom section in the longitudinal direction.

In some implementations, the first bottom section channel layer at the first bottom section has a height in the longitudinal direction greater than that of the first bottom section filling layer at the first bottom section in the longitudinal direction.

In some implementations, a difference between the height of the first bottom section channel layer at the first bottom section in the longitudinal direction and the height of the first bottom section filling layer at the first bottom section in the longitudinal direction is 15 nanometers (nm) to 2 microns (μm).

In some implementations, the first bottom section channel layer and the first bottom section filling layer at the first bottom section and the first dielectric section form a first groove in which the common source layer is disposed.

In some implementations, the first bottom section channel layers of any two of the first bottom sections have equal heights in the longitudinal direction.

In some implementations, the semiconductor device further comprises: a gate line slit structure penetrating the stack structure in the longitudinal direction and having a slit filler bottom section protruding from the first side of the stack structure.

In some implementations, the materials of the first bottom section filling layer and the first dielectric section are the same.

In some implementations, a memory system comprises a memory, and a controller coupled to the memory and configured to control the memory to store data. The memory comprises a stack structure comprising gate conductive layers and interlayer insulating layers alternatively stacked in a longitudinal direction and storage channel structures penetrating the stack structure in the longitudinal direction, with the storage channel structures having a bottom section protruding from a first side of the stack structure. The memory also comprises a common source layer located on the first side of the stack structure. The storage channel structures comprise a first channel structure having a first bottom section, the first bottom section comprises a first bottom section channel layer, a first bottom section filling layer and a first dielectric section on an inner side of the first bottom section channel layer, and the common source layer is disposed to contact the first bottom section channel layer, the first bottom section filling layer and the first dielectric section.

Implementations described herein provide various technical advantages. After inverting the stack structure, the substrate is thinned step by step, the exposed functional layer and the channel layer are removed step by step, which reduces the risk of non-uniform heights of the storage channel structures and improves the yield of the semiconductor devices.

### BRIEF DESCRIPTION OF THE DRAWINGS

In order to explain the technical solutions in implementations of the present application more clearly, accompanying drawings implementations will be described in brief below. The below-described drawings are only some implementations of the present application, and other drawings may be obtained according to these drawings without any creative work for those skilled in the art.

FIG. 1 is a flowchart of steps of a method of fabricating a semiconductor device provided by an implementation of the present application.

FIGS. 2A-2J are structural diagrams corresponding to processes in the method of fabricating a semiconductor device provided by an implementation of the present application.

FIG. 3 is a structural diagram of a semiconductor device provided by an implementation of the present application.

FIG. 4 is a structural diagram of a memory system provided in an implementation of the present application.

FIG. 5 is a structural diagram of an electronic apparatus provided in an implementation of the present application.

### DETAILED DESCRIPTION

The technical solution in implementations of the present application will be described below with reference to accompanying drawings in implementations of the present application. However, the described implementations are only partial implementations rather than all implementations of the present application. Based on the implementations of the present application, all other implementations obtained by those skilled in the art without any creative work fall within the scope of protection of the present application. Furthermore, it will be understood that implementations as described herein are merely used for illustrating and explaining the present application rather than limiting the present application. In the present application, unless otherwise stated, orientation terms such as “upper” and “lower” typically refer to the upper and lower of a device in practical use or operation state which are specifically the drawing direction in the figures; while “inner” and “outer” are used with respect to the profile of a device.

Because NAND flash memory is a non-volatile memory product with low power consumption, light weight, and good performance that can retain stored information in case of power loss, it is widely applied in electronic products. Three-dimensional (3D) NAND (three-dimensional memory) is a novel kind of flash memory that can further improve storage capacity and reduce storage cost relative to two-dimensional (2D) NAND flash memory. In a fabrication method of a relevant 3D NAND structure, a plurality of array devices including a plurality of NAND memory strings are formed on a substrate, and an array interconnection layer and peripheral devices are then formed on the plurality of NAND memory strings. However, while forming channel structures in the plurality of memory strings on the substrate, it is difficult to obtain uniform depths because the depths are large, resulting in reduced yield of the semiconductor devices.

Accordingly, in a fabrication method of a 3D NAND structure, a plurality of array devices including a plurality of NAND memory strings are formed on a first substrate first, and an array interconnection layer is then formed on the plurality of NAND memory strings; the array devices are inverted and the substrate is removed, and a source layer is formed on the back surface of the array devices; then the source layer is led out to connect with the top metal layer so as to connect to external circuits, thereby electrically connecting the array devices with the external circuits for signal output.

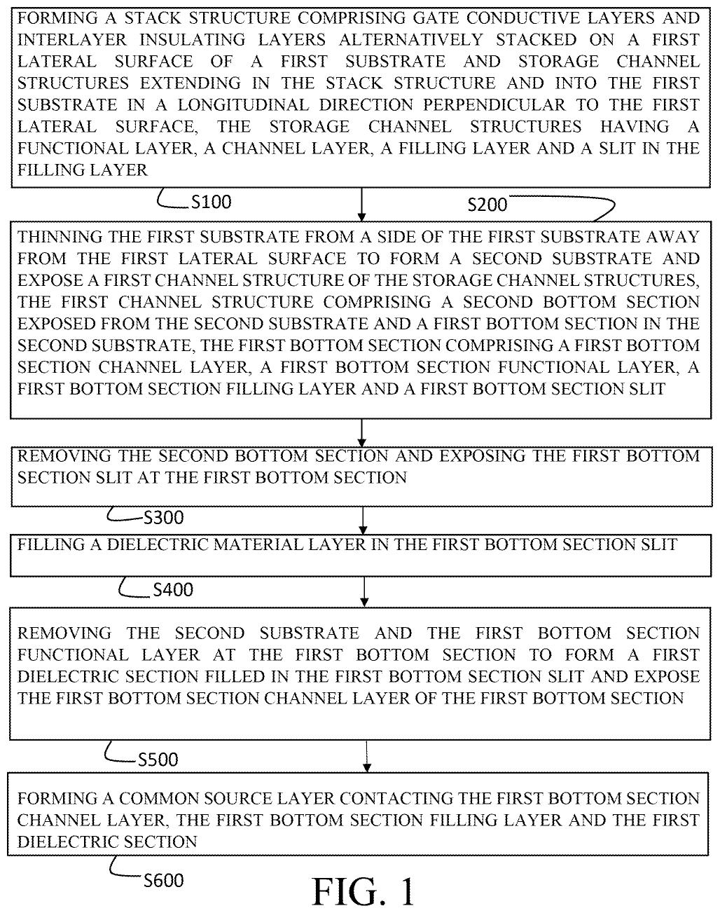

Referring to FIGS. 1-3, an implementation of the present application provides a fabrication method of a semiconductor device 100, including:
step S100: forming a stack structure 200 including gate conductive layers 210 and interlayer insulating layers 220 alternatively stacked on the first lateral surface 2011 of the first substrate 201 and storage channel structures 300 extending in the stack structure 200 and into the first substrate 201 in the longitudinal direction perpendicular to the first lateral surface 2011, the storage channel structures 300 having a functional layer 301, a channel layer 302, a filling layer 303 and a slit 304 in the filling layer 303;
step S200: thinning the first substrate 201 from the side of the first substrate 201 away from the first lateral surface 2011 to form the second substrate 202 and expose the first channel structure 310 of the storage channel structures 300, the first channel structure 310 including a second bottom section 410 exposed from the second substrate 202 and a first bottom section 420 in the second substrate 202, the first bottom section 420 including a first bottom section channel layer 422, a first bottom section functional layer 421, a first bottom section filling layer 423 and a first bottom section slit 424;
step S300: removing the second bottom section 410 and exposing the first bottom section slit 424 at the first bottom section 420;
step S400: filling a dielectric material layer 500 in the first bottom section slit 424;
step S500: removing the second substrate 202 and the first bottom section functional layer 421 at the first bottom section 420 to form the first dielectric section 510 filled in the first bottom section slit 424 and expose the first bottom section channel layer 422 of the first bottom section 420; and
step S600: forming a common source layer 600 contacting the first bottom section channel layer 422, the first bottom section filling layer 423 and the first dielectric section 510.

In the present application, after inverting the stack structure, the substrate is thinned step by step, and the exposed functional layer and the channel layer are removed step by step, which reduces the risk of non-uniform heights of the storage channel structures and improves the yield of the semiconductor devices.

The technical solution of the present application will be described in connection with specific implementations.

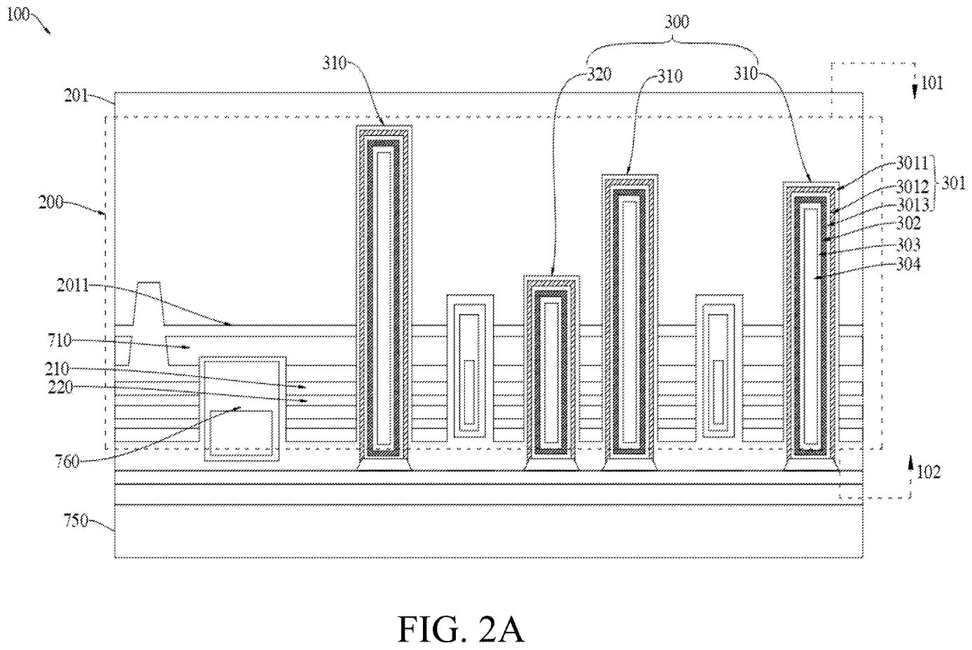

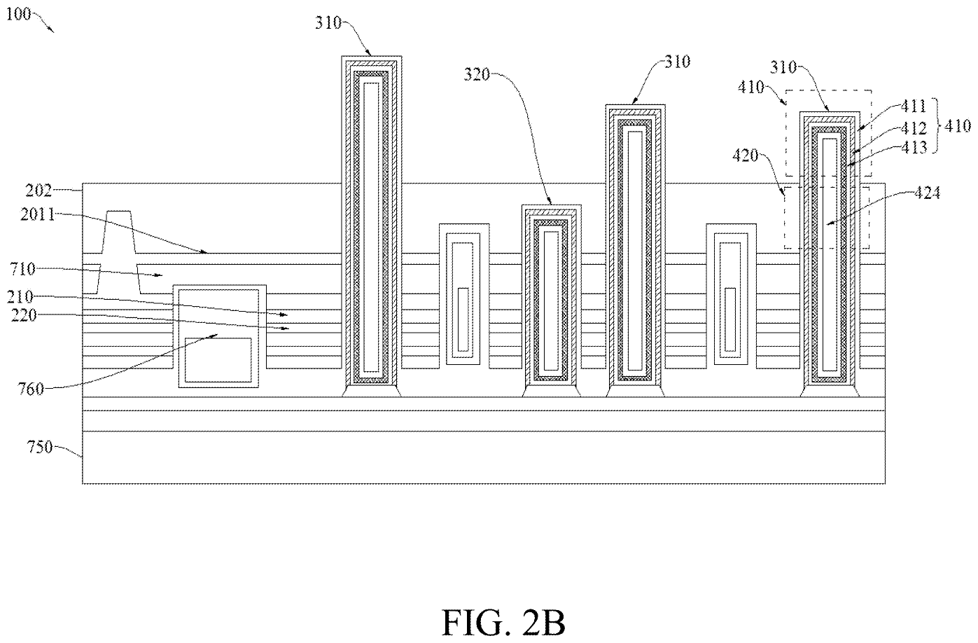

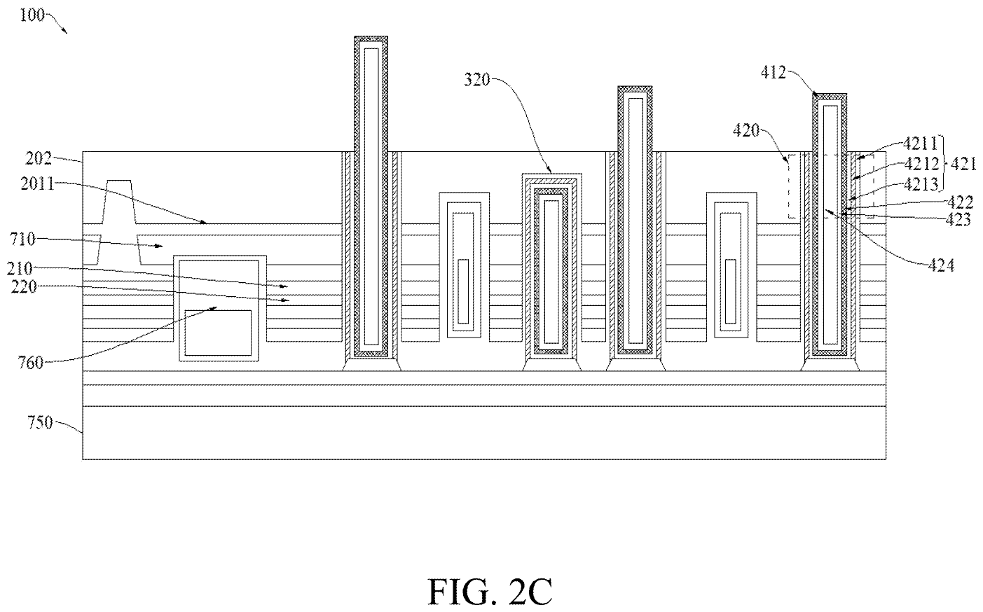

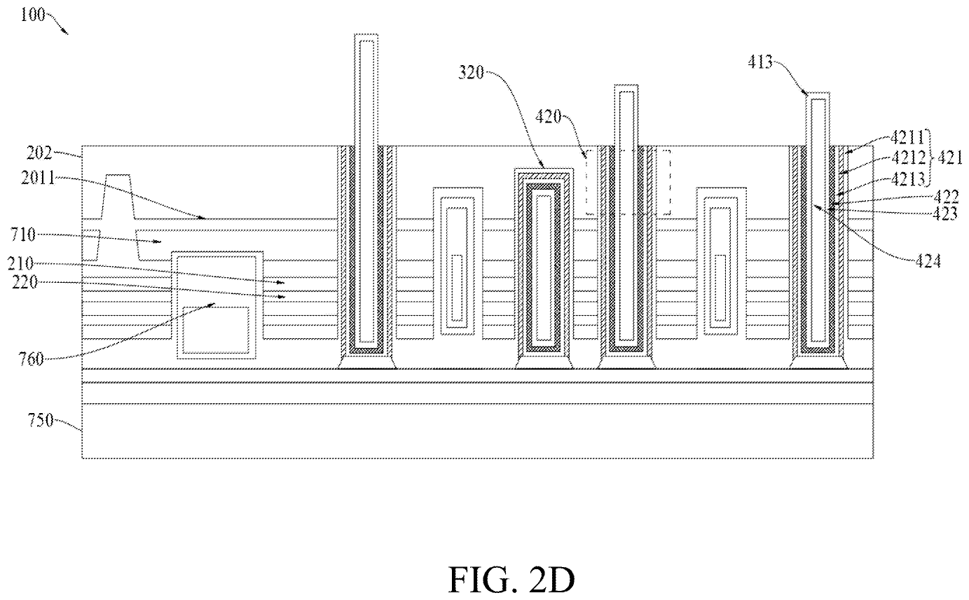

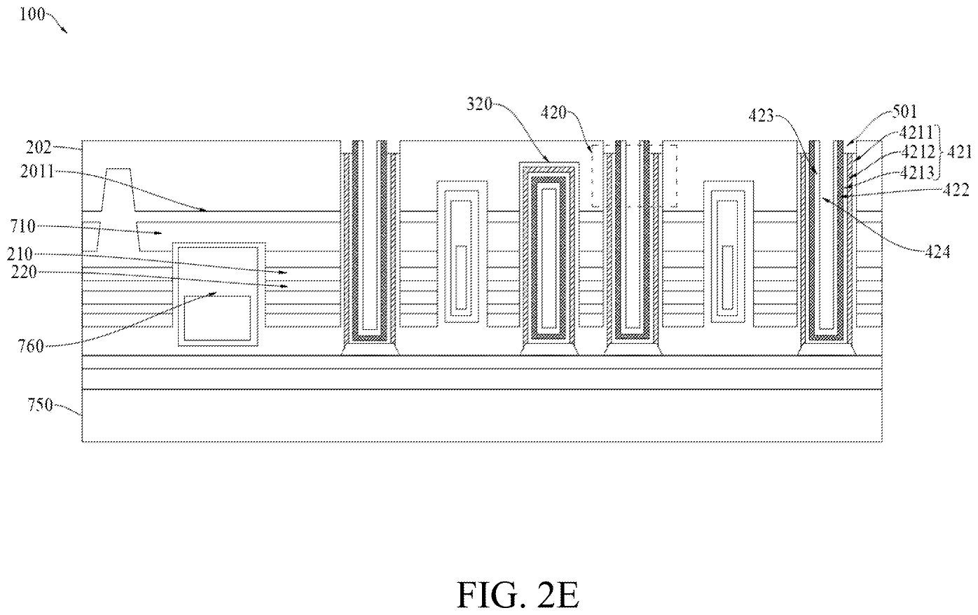

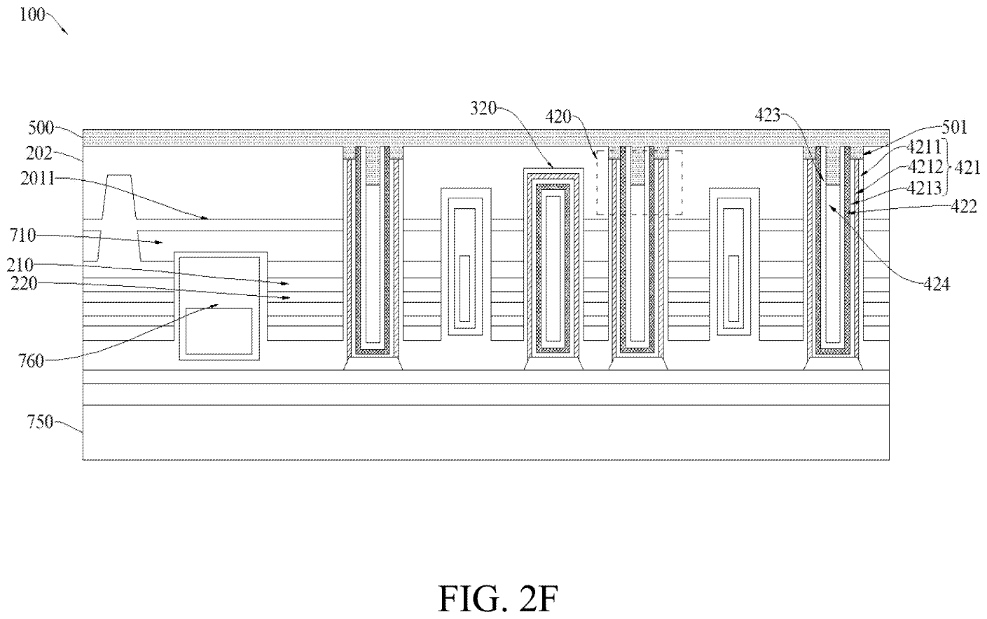

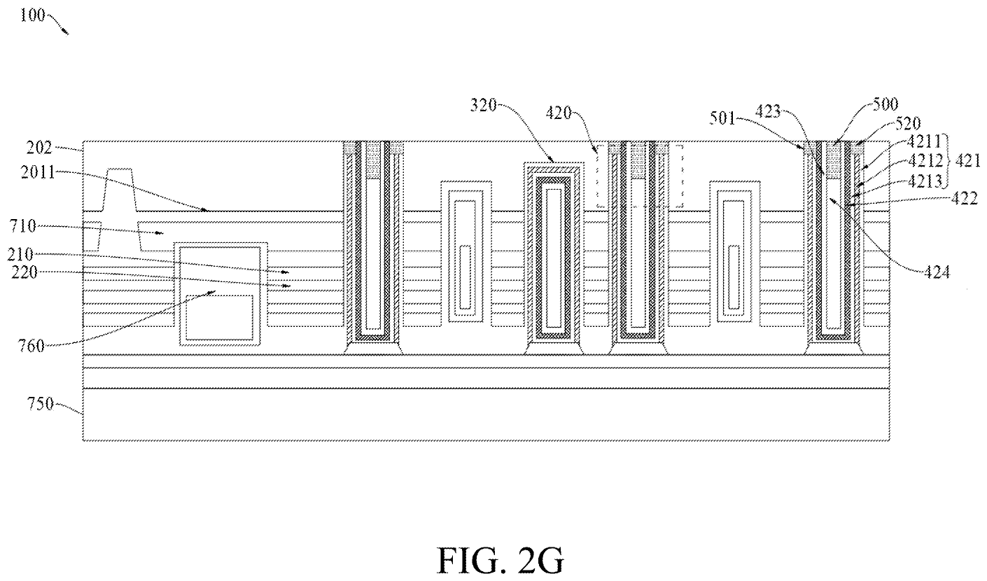

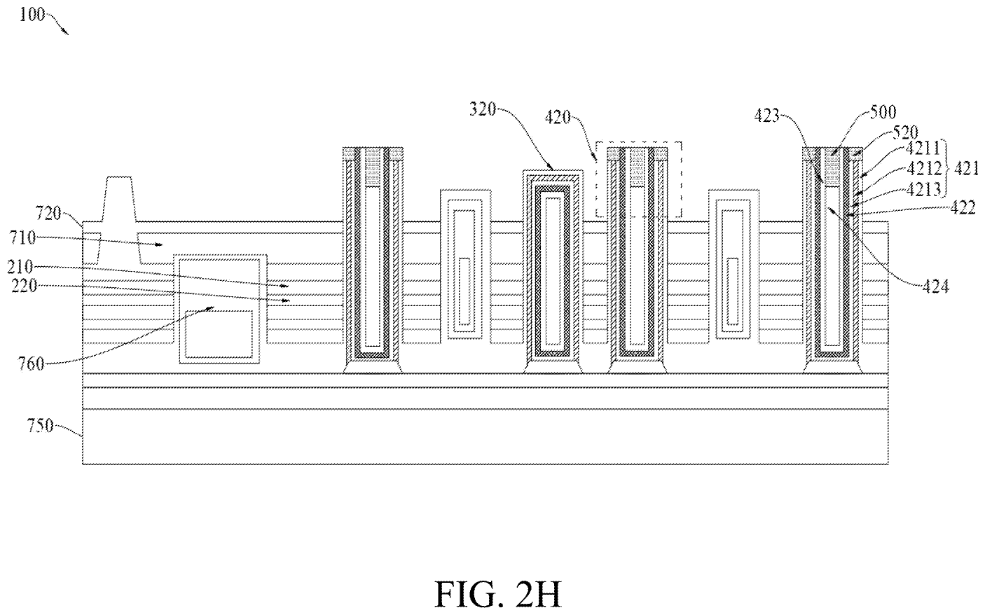

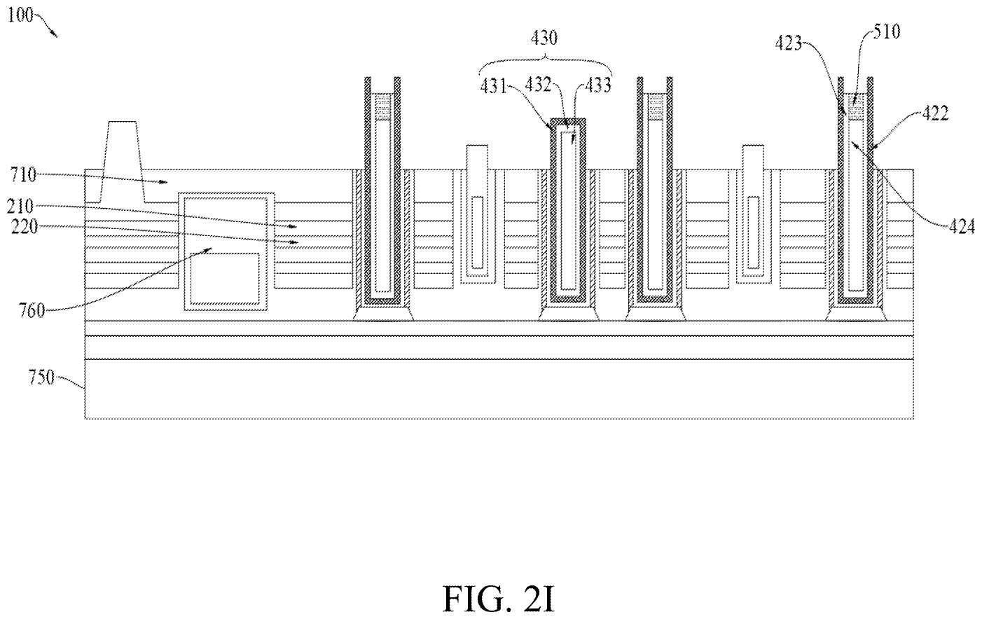

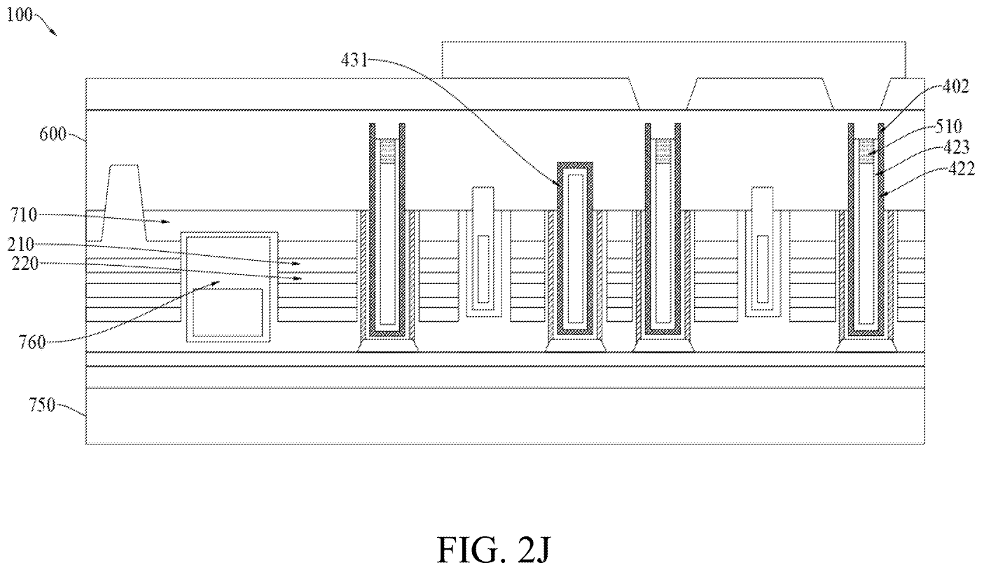

With reference to FIG. 2A, in step S100, a stack structure 200 including gate conductive layers 210 and interlayer insulating layers 220 alternatively stacked on the first lateral surface 2011 of the first substrate 201 and storage channel structures 300 extending in the stack structure 200 and into the first substrate 201 in the longitudinal direction perpendicular to the first lateral surface 2011 are formed. The storage channel structures 300 have a functional layer 301, a channel layer 302, a filling layer 303 and a slit 304 in the filling layer 303.

In some implementations, after forming the stack structure 200, the stack structure 200 is inverted to facilitate removing the first substrate 201 and the arrangement of elements on back surface.

In some implementations, while forming the storage channel structures 300, a filling layer 303 will be filled in the center of the storage channel structure 300. However, there will be slits 304 in the central area of the filling layer 303 of at least part of the channel structures. In subsequent processes, the slits 304 need to be sealed to reduce the risk of abnormal layers such as conductive material entering slits 304, thereby avoiding damages to the storage channel structures 300.

In some implementations, referring to FIG. 2A, the functional layer 301 includes a first layer 3011, a second layer 3012 and a third layer 3013 with the second layer 3012 located between the first layer 3011 and the third layer 3013.

In some implementations, the material for the channel layer 302 may be silicon based material; and further may be polysilicon material including for example monatomic polysilicon or doped polysilicon. Further, the material for the channel layer 302 may further includes at least one of semiconductor materials such as the polycrystalline silicon germanium, carbon silicon and germanium.

In some implementations, the material for the first layer 3011 and the third layer 3013 may be a compound of silicon and oxygen such as silicon dioxide; and the material for the second layer 3012 may be a compound of nitrogen and silicon such as silicon nitride.

Next, referring to FIGS. 2B and 2C, in step S200, the first substrate 201 is thinned from the side of the first substrate 201 away from the first lateral surface 2011 to form the second substrate 202 and expose the first channel structure 310 of the storage channel structures 300. The first channel structure 310 includes a second bottom section 410 exposed from the second substrate 202 and a first bottom section 420 in the second substrate 202, and the first bottom section 420 includes a first bottom section channel layer 422, a first bottom section functional layer 421, a first bottom section filling layer 423 and a first bottom section slit 424.

In some implementations, the second bottom section 410 includes a second bottom section channel layer 412, a second bottom section filling layer 413 on the inner side of the second bottom section channel layer 412 and a second bottom section functional layer 411 on the outer side of the second bottom section channel layer 412.

In some implementations, the channel layer includes a second bottom section channel layer, a first bottom section channel layer and a third bottom section channel layer with the third bottom section channel layer located on a side of the first bottom section channel layer away from the second bottom section channel layer.

The functional layer includes a second bottom section functional layer, a first bottom section functional layer and a third bottom section functional layer with the third bottom section functional layer located on a side of the first bottom section functional layer away from the second bottom section functional layer.

The filling layer includes a second bottom section filling layer, a first bottom section filling layer and a third bottom section filling layer with the third bottom section filling layer located on a side of the first bottom section filling layer away from the second bottom section filling layer.

The functional layer 301 is located on the outer side of the channel layer 302, and the channel layer 302 is located between the functional layer 301 and the filling layer 303.

Next, referring to FIGS. 2C, 2D and 2E, in step S300, the second bottom section 410 is removed and the first bottom section slit 424 at the first bottom section 420 is exposed.

In some implementations, step S300 includes the following operations.

Referring to FIG. 2C, in step S310, the second bottom section functional layer 411 on the outer side of the second bottom section channel layer 412 of the second bottom section 410 is removed to expose the second bottom section channel layer 412 of the second bottom section 410.

Next, referring to FIG. 2D, in step S320, the second bottom section channel layer 412 of the second bottom section 410 is removed to expose the second bottom section filling layer 413 on the inner side of the second bottom section channel layer 412 of the second bottom section 410.

“Outer side” refers to the side of a layer away from the center of the structure to which the layer belongs, and “inner side” refers to the side of a layer proximate to the center of the structure to which the layer belongs. For example, the outer side of the second bottom section channel layer 412 refers to the side of the second bottom section channel layer 412 away from the center of the second bottom section 410 or the side of the second bottom section channel layer 412 away from the center of the first channel structure 310; and the inner side of the second bottom section channel layer 412 refers to the side of the second bottom section channel layer 412 proximate to the center of the second bottom section 410 or the side of the second bottom section channel layer 412 proximate to the center of the first channel structure 310. The orientation of inner or outer side of the first bottom section channel layer 422 in the following description is the same and will not be repeated.

Next, referring to FIG. 2E, in step S330, the second bottom section filling layer 413 is removed and the first bottom section slit 424 at the first bottom section 420 and not sealed by the first bottom section filling layer 423 is exposed.

The second bottom section 410 is removed first (because of the second substrate 202 supporting from bottom, the first bottom section 420 will not topple), to reduce the height of the first channel structure 310 exposed from the second substrate 202 and at the same time reduce the height of the first channel structure 310 protruding the gate conductive layer 210 of the stack structure 200, which reduces the risk of collapse of the storage channel structure 300, controls the height of the first channel structure 310 exposed from the second substrate well, reduces the risk of non-uniform heights of the storage channel structures, and improves the yield of the semiconductor devices 100.

In some implementations, step S330 includes the following operations.

Referring to FIGS. 2D and 2E, in step S331, the second bottom section filling layer 413 on the inner side of the second bottom section channel layer 412 of the second bottom section 410 is removed and the first bottom section functional layer 421 on the outer side of the first bottom section channel layer 422 of the first bottom section 420 is thinned to form the first recess 501.

While removing the second bottom section filling layer 413, a part of the first bottom section functional layer 421 will be removed inevitably, therefore, the first recess 501 will be formed while thinning the first bottom section functional layer 421 in step S331.

In some implementations, the first bottom section functional layer 421 includes a first oxide layer 4211, a first nitride layer 4212 and a second oxide layer 4213 with the first nitride layer 4212 located between the first oxide layer 4211 and the second oxide layer 4213 and the first oxide layer 4211 located on the side of the first nitride layer 4212 away from the first bottom section channel layer 422.

The first layer 3011 includes the first oxide layer 4211, the second layer 3012 includes the first nitride layer 4212, and the third layer 3013 includes the second oxide layer 4213.

Next, referring to FIG. 2F, in step S400, a dielectric material layer 500 is filled in the first bottom section slit 424.

In some implementations, step S400 includes the following operations.

Referring to FIG. 2F, in step S410, a dielectric material layer 500 is formed on the second substrate 202 to fill the dielectric material layer 500 in the first bottom section slit 424 and the first recess 501.

In some implementations, referring to FIG. 2G, a dielectric material layer 500 is formed on the second substrate 202 to fill the dielectric material layer 500 in the first bottom section slit 424 and the first recess 501, thereby forming a second dielectric section 520 in the first recess 501.

Next, referring to FIGS. 2H and 2I, in step S500, the second substrate 202 and the first bottom section functional layer 421 at the first bottom section 420 are removed to form the first dielectric section 510 filled in the first bottom section slit 424 and expose the first bottom section channel layer 422 of the first bottom section 420.

In some implementations, step S500 includes the following operations.

Referring to FIG. 2H, in step S510, the second substrate 202 is removed.

Next, referring to FIG. 2I, in step S520, the first bottom section functional layer 421 in the first bottom section 420 is removed.

Next, referring to FIG. 2I, in step S530, the first dielectric section 510 filled in the first bottom section slit 424 is formed and the first bottom section channel layer 422 of the first bottom section 420 is exposed.

In some implementations, step S510 includes the following operations.

Referring to FIGS. 2F and 2G, in step S511, the dielectric material layer 500 on the second substrate 202 is removed.

Next, referring to FIG. 2H, in step S512, the second substrate 202 is removed to expose the first bottom section functional layer 421 of the first bottom section 420.

The second substrate 202 is removed to expose the sidewall of the first bottom section functional layer 421 away from the first bottom section channel layer 422.

Next, referring to FIG. 2I, in step S520, the first bottom section functional layer 421 at the first bottom section 420 is removed to expose the first bottom section channel layer 422 of the first bottom section 420.

In some implementations, step S520 includes the following operations.

In step S521, the first oxide layer 4211 at the first bottom section 420 is removed to expose the first nitride layer 4212.

Next, in step S522, the first nitride layer 4212 is removed to expose the second oxide layer 4213.

Next, referring to FIG. 2I, in step S523, the second oxide layer 4213 is removed to expose the first bottom section channel layer 422 of the first bottom section 420.

In some implementations, referring to FIGS. 2H and 2I, the stack structure 200 further includes a termination layer 710 located between the first substrate 201 and the gate conductive layer 210 and the interlayer insulating layer 220; and the semiconductor device further includes a first insulating layer 720 on a side of the termination layer 710 away from the gate conductive layer 210.

Referring to FIG. 2I, the step of removing the first oxide layer 4211 includes removing the first oxide layer 4211 and removing the first insulating layer 720.

In some implementations, referring to FIGS. 2A and 2I, the storage channel structures 300 further include a second channel structure 320 having a third bottom section 430 that includes a third bottom section channel layer 431, a third bottom section filling layer 432 on the inner side of the third bottom section channel layer 431 and a third bottom section slit 433 located in the third bottom section filling layer 432 and sealed by the third bottom section filling layer 432.

After completing step S500, referring to FIG. 2I, the third bottom section channel layer 431 of the second channel structure 320 is similarly exposed to facilitate subsequent connection of common source layer.

In some implementations, the step of removing the dielectric material layer 500 outside the first bottom section slit 424 includes:
step S511 as shown in FIGS. 2F and 2G.

Referring to FIG. 2I, the dielectric material layer 500 in the first recess 501 is removed and the dielectric material layer 500 in the first bottom section slit 424 is thinned.

In some implementations, referring to FIGS. 2H and 2I, the step of removing the dielectric material layer 500 in the first recess 501 includes removing the second dielectric section 520.

In some implementations, referring to FIGS. 2H and 2I, the step of forming the first dielectric section 510 filled in the first bottom section slit 424 includes:
removing the dielectric material layer 500 outside the first bottom section slit 424 to form the first dielectric section 510 filled in the first bottom section slit 424.

In some implementations, referring to FIGS. 2H and 2I, the step of removing the first bottom section functional layer 421 at the first bottom section 420 includes:
removing the first bottom section functional layer 421 of the first bottom section 420, removing the second dielectric section 520, thinning the first bottom section filling layer 423 at the first bottom section 420 and thinning the dielectric material layer 500 in the first bottom section slit 424.

While removing the first bottom section functional layer 421, the first bottom section filling layer 423 and the dielectric material layer 500 in the first bottom section slit 424 will also be thinned. Therefore, upon subsequent formation of the common source layer 600, the common source layer 600 may not only contact the outer side of the first bottom section channel layer 422, but also contact the inner side of the first bottom section channel layer 422, thereby increasing the contact area and improving the stability of electrical connection.

In some implementations, the material for the first bottom section filling layer 423 may be a compound of silicon and oxygen, a compound of nitrogen and silicon.

In some implementations, the material for the dielectric material layer 500 may be a compound of silicon and oxygen, a compound of nitrogen and silicon or a compound of nitrogen, oxygen and silicon.

In some implementations, the material for the dielectric material layer 500 may be the same as the material for the first bottom section filling layer 423.

In some implementations, the material for the dielectric material layer 500 may also be different from the material for the first bottom section filling layer 423, and an interface may be observed upon dicing in case of different materials.

Next, referring to FIG. 2J, in step S600, a common source layer 600 contacting the first bottom section channel layer 422, the first bottom section filling layer 423 and the first dielectric section 510 is formed.

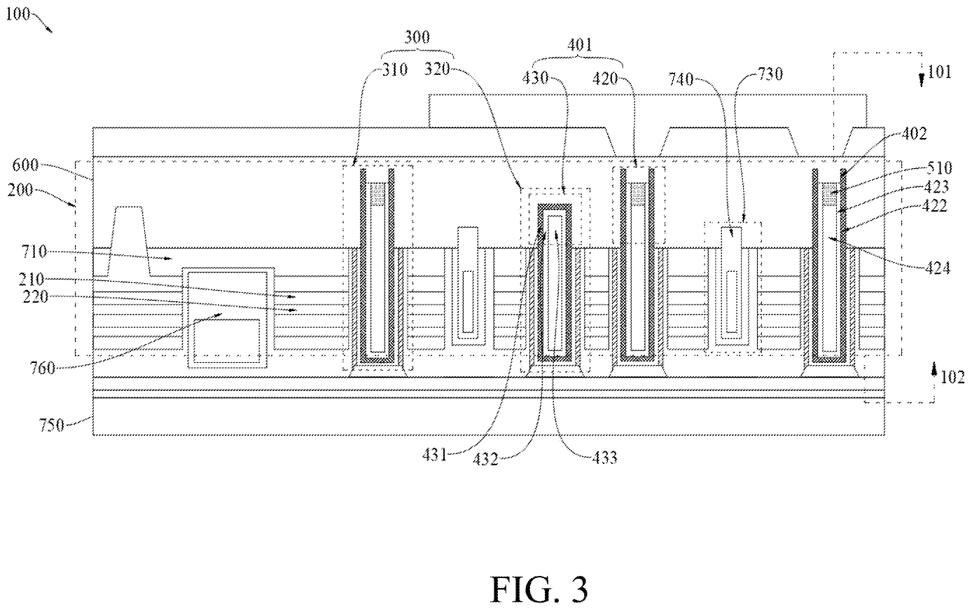

In some implementations, referring to FIG. 3, the common source layer 600 is disposed to contact the third bottom section channel layer 431.

The common source layer 600 is utilized to connect the first channel structure 310 and the second channel structure 320 for leading out of the source, thereby simplifying the arrangement of leads.

In the present application, after inverting the stack structure, the substrate is thinned step by step, the exposed functional layer and the channel layer are removed step by step so as to well control the height of the storage channel structure exposed from the second substrate, which reduces the risk of non-uniform heights of the storage channel structures and improves the yield of the semiconductor devices.

Referring to FIG. 3, the implementations of the present application further provide a semiconductor device 100, including:
a stack structure 200 including gate conductive layers 210 and interlayer insulating layers 220 alternatively stacked in the longitudinal direction and storage channel structures 300 penetrating the stack structure 200 in the longitudinal direction, the storage channel structures 300 having a bottom section 401 protruding from the first side 101 of the stack structure 200; and
a common source layer 600 on the first side 101 of the stack structure 200;
wherein the storage channel structures 300 includes a first channel structure 310 having the first bottom section 420 including a first bottom section channel layer 422 and a first bottom section filling layer 423 and a first dielectric section 510 on the inner side of the first bottom section channel layer 422, and the common source layer 600 is disposed to contact the first bottom section channel layer 422, the first bottom section filling layer 423 and the first dielectric section 510.

In the present application, after inverting the stack structure, the substrate is thinned step by step, the exposed functional layer and the channel layer are removed step by step, which reduces the risk of non-uniform heights of the storage channel structures and improves the yield of the semiconductor devices.

The technical solution of the present application will be described in connection with specific implementations.

In the present implementation, referring to FIG. 3, the first bottom section filling layer 423 and the first dielectric section 510 form a closed pattern to isolate the slit 304 of the first channel structure 310, preventing the common source layer 600 from entering the first channel structure 310, reducing the risk of conductive material entering the slit 304 and avoiding damage to the storage channel structures 300.

In some implementations, referring to FIG. 3, the first bottom section 420 further includes a first bottom section slit 424 sealed by the first bottom section filling layer 423 and the first dielectric section 510.

With the first bottom section slit 424 sealed by the first bottom section filling layer 423 and the first dielectric section 510, in the fabrication process, particularly in the formation process of the conductive material, the risk of conductive material entering the slit 304 is reduced and damage to the storage channel structures 300 is avoided.

In some implementations, referring to FIG. 2A, the stack structure 200 includes alternatively stacked gate conductive layers 210 and interlayer insulating layers 220 and storage channel structures 300 perpendicular to the gate conductive layers 210, and the storage channel structures 300 have a functional layer 301, a channel layer 302, a filling layer 303 and a slit 304 in the filling layer 303.

In some implementations, referring to FIG. 2A, the functional layer 301 includes a first layer 3011, a second layer 3012 and a third layer 3013 with the second layer 3012 located between the first layer 3011 and the third layer 3013.

In some implementations, the material for the channel layer 302 may be silicon based material; and further may be polysilicon material including for example monatomic polysilicon or doped polysilicon. Further, the material for the channel layer 302 may further includes at least one of semiconductor materials such as the polycrystalline silicon germanium, carbon silicon and germanium. The doping ions may be TiN, Ta, Cr, etc.

In some implementations, referring to FIG. 3, the channel layer 302 includes the first bottom section channel layer 422.

In some implementations, the material for the common source layer 600 may be silicon based material; and further may be polysilicon material including for example monatomic polysilicon or doped polysilicon. Further, the material for the channel layer 302 may further include at least one of semiconductor materials such as the polycrystalline silicon germanium, carbon silicon and germanium. The doping ions may be TiN, Ta, Cr, etc.

The material for the common source layer 600 may be the same as that for the channel layer 302.

The material for the common source layer 600 may also be different from that for the channel layer 302. An interface between the material for the common source layer 600 and the first bottom section channel layer 422 may be observed upon dicing regardless of same or different materials for the common source layer 600 and the channel layer 302.

In some implementations, referring to FIG. 3, the storage channel structures 300 further include a second channel structure 320 having a third bottom section 430 that includes a third bottom section channel layer 431 and a third bottom section filling layer 432 on the inner side of the third bottom section channel layer 431; wherein the common source layer 600 is disposed to contact the third bottom section channel layer 431.

The common source layer 600 is disposed to contact the third bottom section channel layer 431 to connect signals of the third bottom section channel layer 431, facilitating connection with external circuits.

In some implementations, referring to FIG. 3, the third bottom section 430 further includes a third bottom section slit 433 located in the third bottom section filling layer 432 and sealed by the third bottom section filling layer 432.

In the fabrication process, the second channel structure 320 is not opened, and the third bottom section slit 433 thereof is directly sealed by the third bottom section fill layer 432, thereby reducing the risk of conductive material entering slit 304 and avoiding damage to the storage channel structures 300.

In some implementations, referring to FIG. 3, the third bottom section channel layer 431 at the third bottom section 430 has a height in longitudinal direction smaller than that of the first bottom section channel layer 422 at the first bottom section 420 in longitudinal direction.

In the fabrication process, the second channel structure 320 is not shortened and has a smaller height than the first channel structure 310, hence remaining a short channel structure. At the same time, the third bottom section slit 433 of the second channel structure 320 is directly scaled by the third bottom section filling layer 432, resulting in a better continuity of the layer and a better sealing effect.

In some implementations, the difference between the height of the third bottom section channel layer 431 at the third bottom section 430 in longitudinal direction and the height of the first bottom section channel layer 422 at the first bottom section 420 in longitudinal direction is less than or equal to 2.5 μm, since a too large height difference may influence the quality uniformity of the overall channel structure.

In some implementations, referring to FIG. 3, the first bottom section channel layer 422 at the first bottom section 420 has a height in longitudinal direction greater than that of the first bottom section filling layer 423 at the first bottom section 420 in longitudinal direction.

In some implementations, referring to FIG. 3, the first bottom section channel layer 422 and the first bottom section filling layer 423 at the first bottom section 420 and the first dielectric section 510 form a first groove 402 in which a common source layer 600 is disposed.

While removing the first bottom section functional layer 421, the first bottom section filling layer 423 and the dielectric material layer 500 in the first bottom section slit 424 will also be thinned. Therefore, upon subsequent formation of the common source layer 600, the common source layer 600 may not only contact the outer wall of the first bottom section channel layer 422, but also contact the inner wall of the first bottom section channel layer 422, thereby increasing the contact area and improving the stability of electrical connection.

In some implementations, the difference between the height of the first bottom section channel layer 422 at the first bottom section 420 in longitudinal direction and the height of the first bottom section filling layer 423 at the first bottom section 420 in longitudinal direction is 15 nm to 2 μm. This can not only guarantee an increased contact area, improve the stability of electrical connection, but also avoid a too large height difference that influences the coverage of layers.

In some implementations, referring to FIG. 3, the two corresponding first bottom section channel layers 422 of any two first bottom sections 420 have equal heights in longitudinal direction.

First channel structures 310 having equal heights can improve performance uniformity of channel structures and improve performance uniformity of semiconductor devices 100.

For the first channel structures 310, substrates are thinned step by step, and exposed functional layers 301 and channel layers 302 are removed step by step, so their theoretical heights are equal. In practical fabrication process, there might be errors of 100 nm to 200 nm due to fabrication accuracy or non-uniformity of layer properties. As a comprehensive consideration, two corresponding first bottom section channel layers 422 of any two first bottom sections 420 having a height difference in the longitudinal direction less than 1 μm may be regarded as the two corresponding first bottom section channel layers 422 of any two first bottom sections 420 having equal heights in the longitudinal direction.

In some implementations, referring to FIG. 3, the semiconductor device 100 further includes a gate line slit structure 730 penetrating the stack structure 200 in the longitudinal direction and having a slit filler bottom section 740 protruding from a first side 101 of the stack structure 200.

In some implementations, the semiconductor device 100 further includes a contact structure 760 that is located on a side away from the center of the semiconductor device 100 and electrically connected with the gate conductive layer 210 of the stack structure 200, thereby leading out the gate conductive layer 210 to be in electrical communication with external elements. There may be a plurality of contact structures 760.

In some implementations, referring to FIG. 3, the semiconductor device 100 further includes a planar layer 750 located on a second side 102 of the stack structure 200.

In the figure, the semiconductor device 100 is in an inverted state, with the first side 101 as upper side and the second side 102 as the lower side.

In some implementations, depending on practical products, the first channel structure 310 proximate to the contact structure 760 may be set as a dummy channel structure.

In the present application, after inverting the stack structure, the substrate is thinned step by step, the exposed functional layer and the channel layer are removed step by step so as to well control the height of the storage channel structures exposed from the second substrate, which reduces the risk of non-uniform heights of the storage channel structures and improves the yield of the semiconductor devices.

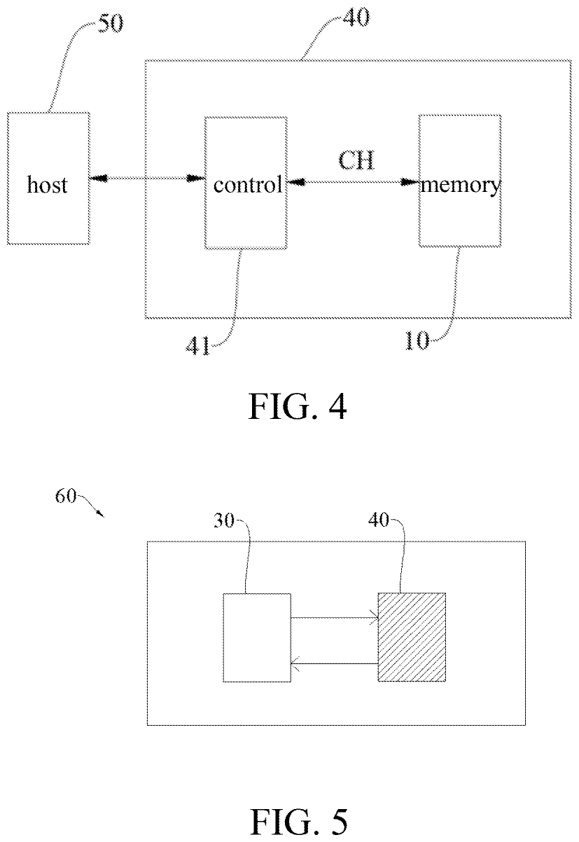

Referring to FIG. 4, an implementation of the present application further provides a memory system. The memory system 40 includes a controller 41 and a memory 10, wherein the controller 41 is coupled to the memory 10 and configured to control the memory 10 to store data, and the memory 10 includes the semiconductor device according to any one of the above-described implementations.

The semiconductor device may be an array wafer/array memory device or a device bound with CMOS (complementary metal oxide semiconductor) peripheral circuits.

The semiconductor device 100 may be stacked with the peripheral circuits or disposed staggered with peripheral circuits, which is not limited herein. The peripheral circuits are electrically connected with the semiconductor device 100 to communicate signals with the semiconductor device 100. The peripheral circuits may be configured to implement logical operations and control and detect on-off states of the respective memory cells in the above-mentioned semiconductor device 100 via metal lines for data storing and reading.

The above-mentioned memory 10 may be embodied as a three-dimensional memory such as a 3D NAND memory.

In particular, the controller 41 may control the memory 10 through a channel CH and the memory 10 may execute operations based on the control by the controller 41 in response to the request from the host 50. The memory 10 may receive a command CMD and an address ADDR from the controller 41 through the channel CH and access regions selected from the memory cell array in response to the address. In other words, the memory 10 may execute internal operations corresponding to the command on the regions selected by the address.

In some implementations, the memory system 40 may be implemented as multimedia card such as universal Flash storage (UFS) device, solid state hard disk (SSD), MultiMediaCard (MMC), embedded MMC (eMMC), reduced-size MMC (RS-MMC) and mini-MMC, secure digital card such as SD, mini-SD and micro-SD, storage device of Personal Computer Memory Card International Association (PCMCIA) type, storage device of peripheral component interconnect (PCI) type, storage device of PCI Express (PCI-E) type, compact flash (CF) card, smart media card or memory stick, etc.

The above-described memory system 40 may be used in a computer, a TV, a set-top box, and/or an on-vehicle terminal product.

Referring to FIG. 5, an implementation of the present application further provides an electronic apparatus 60 including a central processor 30 and the above-described memory system 40 as provided in the implementations of the present application. In particular, the electronic apparatus 60 may be any device that may store data such as a mobile phone, a desktop computer, a tablet computer, a notebook computer, a server, an on-vehicle device, a wearable device, a mobile power source, etc.

The central processor 30 is configured to exchange information and data with the memory system 40.

Since the electronic device provided in the implementation of the present application is provided with the memory system provided in implementations of the present application, it has the same beneficial effects as the above-described memory system.

Implementations of the present application disclose a semiconductor device and a fabrication method thereof, a memory system and an electronic apparatus. The fabrication method of the semiconductor device includes forming storage channel structures having a functional layer, a channel layer, a filling layer and a slit in the filling layer, thinning a first substrate to form a second substrate, removing a second bottom section outside the second substrate to expose a first bottom section slit, filling a dielectric material layer in the first bottom section slit, removing the second substrate and the first bottom section functional layer to form a first dielectric section filled in the first bottom section slit and expose the first bottom section channel layer, forming a common source layer contacting the first bottom section channel layer, the first bottom section filling layer and the first dielectric section. In the present application, after inverting the stack structure, the substrate is thinned step by step, the exposed functional layer and the channel layer are removed step by step, which reduces the risk of non-uniform heights of the storage channel structures and improves the yield of the semiconductor devices.

The semiconductor device and the fabrication method thereof, the memory system and the electronic apparatus provided in implementations of the present application have been described in detail above. Specific examples are used herein to set forth the principle and implementations of the present application and description of the above implementations is only for assisting the understanding of the method and gist thereof of the present application. Meanwhile, those skilled in the art may make modifications to implementations and application ranges according to the idea of the present application. In summary, the contents of the present specification should not be construed as limiting the present application.

What is claimed is:

1. A method for fabricating a semiconductor device, comprising:
forming a stack structure comprising gate conductive layers and interlayer insulating layers alternatively stacked on a first lateral surface of a first substrate and storage channel structures extending in the stack structure and into the first substrate in a longitudinal direction perpendicular to the first lateral surface, the storage channel structures having a functional layer, a channel layer, a filling layer and a slit in the filling layer;
thinning the first substrate from a side of the first substrate away from the first lateral surface to form a second substrate and expose a first channel structure of the storage channel structures, the first channel structure comprising a second bottom section exposed from the second substrate and a first bottom section in the second substrate, the first bottom section comprising a first bottom section channel layer, a first bottom section functional layer, a first bottom section filling layer and a first bottom section slit;
removing the second bottom section and exposing the first bottom section slit at the first bottom section;
filling a dielectric material layer in the first bottom section slit;
removing the second substrate and the first bottom section functional layer at the first bottom section to form a first dielectric section filled in the first bottom section slit and expose the first bottom section channel layer of the first bottom section; and
forming a common source layer contacting the first bottom section channel layer, the first bottom section filling layer and the first dielectric section.

2. The method of claim 1, wherein the second bottom section comprises a second bottom section channel layer, a second bottom section filling layer on an inner side of the second bottom section channel layer, and a second bottom section functional layer on an outer side of the second bottom section channel layer;
wherein the step of removing the second bottom section comprises:
removing the second bottom section functional layer on the outer side of the second bottom section channel layer of the second bottom section to expose the second bottom section channel layer of the second bottom section;
removing the second bottom section channel layer at the second bottom section to expose the second bottom section filling layer on the inner side of the second bottom section channel layer of the second bottom section; and
removing the second bottom section filling layer.

3. The method of claim 2, wherein the step of removing the second bottom section filling layer on the inner side of the second bottom section channel layer of the second bottom section comprises:
removing the second bottom section filling layer on the inner side of the second bottom section channel layer of the second bottom section and thinning the first bottom section functional layer on the outer side of the first bottom section channel layer of the first bottom section to form a first recess;
wherein the step of filling the dielectric material layer in the first bottom section slit comprises:
forming a dielectric material layer on the second substrate to fill the dielectric material layer in the first bottom section slit and the first recess;
wherein the step of forming the first dielectric section filled in the first bottom section slit comprises:
removing the dielectric material layer outside the first bottom section slit to form the first dielectric section filled in the first bottom section slit.

4. The method of claim 3, wherein the step of removing the dielectric material layer outside the first bottom section slit comprises:
removing the dielectric material layer on the second substrate; and
removing the dielectric material layer in the first recess and thinning the dielectric material layer in the first bottom section slit to form the first dielectric section filled in the first bottom section slit.

5. The method of claim 4, wherein the step of forming the dielectric material layer on the second substrate to fill the dielectric material layer in the first bottom section slit and the first recess comprises:
forming the dielectric material layer on the second substrate to fill the dielectric material layer in the first bottom section slit and the first recess to form a second dielectric section in the first recess;
wherein the step of removing the dielectric material layer in the first recess comprises:
removing the second dielectric section;
wherein the step of removing the second substrate is between the step of removing the dielectric material layer on the second substrate and the step of removing the second dielectric section.

6. The method of claim 5, wherein the step of removing the first bottom section functional layer at the first bottom section comprises:
removing the first bottom section functional layer at the first bottom section, removing the second dielectric section, thinning the first bottom section filling layer at the first bottom section and thinning the dielectric material layer in the first bottom section slit.

7. The method of claim 1, wherein the first bottom section functional layer comprises a first oxide layer, a first nitride layer and a second oxide layer, wherein the first nitride layer is between the first oxide layer and the second oxide layer, and the first oxide layer is on a side of the first nitride layer away from the first bottom section channel layer;
wherein the step of removing the first bottom section functional layer at the first bottom section comprises:
removing the first oxide layer, removing the first nitride layer and removing the second oxide layer.

8. The method of claim 7, wherein the stack structure further comprises a termination layer between the first substrate and the gate conductive layer and the interlayer insulating layer;
wherein the semiconductor device further comprises a first insulating layer on a side of the termination layer away from the gate conductive layer;
wherein the step of removing the first oxide layer comprises:
removing the first oxide layer and removing the first insulating layer.

9. A semiconductor device, comprising:
a stack structure comprising gate conductive layers and interlayer insulating layers alternatively stacked in a longitudinal direction and storage channel structures penetrating the stack structure in the longitudinal direction, the storage channel structures having a bottom section protruding from a first side of the stack structure; and
a common source layer located on the first side of the stack structure;
wherein the storage channel structures comprise a first channel structure having a first bottom section, the first bottom section comprises a first bottom section channel layer, a first bottom section filling layer and a first dielectric section on an inner side of the first bottom section channel layer, and the common source layer is disposed to contact the first bottom section channel layer, the first bottom section filling layer and the first dielectric section.

10. The semiconductor device of claim 9, wherein the first bottom section further comprises a first bottom section slit sealed by the first bottom section filling layer and the first dielectric section.

11. The semiconductor device of claim 9, wherein the storage channel structures further comprise a second channel structure having a third bottom section, and the third bottom section comprises a third bottom section channel layer and a third bottom section filling layer on an inner side of the third bottom section channel layer;
wherein the common source layer is disposed to contact the third bottom section channel layer.

12. The semiconductor device of claim 11, wherein the third bottom section further comprises a third bottom section slit located in and sealed by the third bottom section filling layer.

13. The semiconductor device of claim 11, wherein the third bottom section channel layer at the third bottom section has a height in the longitudinal direction smaller than that of the first bottom section channel layer at the first bottom section in the longitudinal direction.

14. The semiconductor device of claim 9, wherein the first bottom section channel layer at the first bottom section has a height in the longitudinal direction greater than that of the first bottom section filling layer at the first bottom section in the longitudinal direction.

15. The semiconductor device of claim 14, wherein a difference between the height of the first bottom section channel layer at the first bottom section in the longitudinal direction and the height of the first bottom section filling layer at the first bottom section in the longitudinal direction is 15 nm to 2 μm.

16. The semiconductor device of claim 14, wherein the first bottom section channel layer and the first bottom section filling layer at the first bottom section and the first dielectric section form a first groove in which the common source layer is disposed.

17. The semiconductor device of claim 9, wherein the first bottom section channel layers of any two of the first bottom sections have equal heights in the longitudinal direction.

18. The semiconductor device of claim 9, wherein the semiconductor device further comprises:
a gate line slit structure penetrating the stack structure in the longitudinal direction and having a slit filler bottom section protruding from the first side of the stack structure.

19. The semiconductor device of claim 9, wherein the materials of the first bottom section filling layer and the first dielectric section are the same.

20. A memory system, comprising:
a memory; and
a controller coupled to the memory and configured to control the memory to store data;
wherein the memory comprises:
a stack structure comprising gate conductive layers and interlayer insulating layers alternatively stacked in a longitudinal direction and storage channel structures penetrating the stack structure in the longitudinal direction, the storage channel structures having a bottom section protruding from a first side of the stack structure; and
a common source layer located on the first side of the stack structure;
wherein the storage channel structures comprise a first channel structure having a first bottom section, the first bottom section comprises a first bottom section channel layer, a first bottom section filling layer and a first dielectric section on an inner side of the first bottom section channel layer, and the common source layer is disposed to contact the first bottom section channel layer, the first bottom section filling layer and the first dielectric section.
